(19) United States
(12) Patent Application Publication
(10) Pub. No.: US 2026/0206530 A1
(43) Pub. Date: Jul. 16, 2026

(54) TRANSPORT DEVICE, TRANSPORT SYSTEM USING THE SAME AND OPERATION METHOD THEREOF

(71) Applicant: Taiwan Semiconductor Manufacturing Company, Ltd., Hsinchu (TW)

(72) Inventors: Yen I LEE, Hsinchu (TW); Chun-Jung HUANG, Hsinchu (TW); Chin-Lung TSAI, Hsinchu (TW); Fu-Hsien LI, Hsinchu (TW)

(73) Assignee: Taiwan Semiconductor Manufacturing Company, Ltd., Hsinchu (TW)

(21) Appl. No.: 19/020,453

(22) Filed: Jan. 14, 2025

(51) Int. Cl. H01L 21/673; B66C 13/23; B66C 13/46; B66C 19/00; H01L 21/677; H01L 21/68

(52) U.S. Cl. CPC H10P 72/1926; B66C 13/23; B66C 13/46; B66C 19/002; H10P 72/3218; H10P 72/3221; H10P 72/53

(57) ABSTRACT

A transport device for holding a wafer container is provided. The transport device includes a vehicle, a gas cylinder, a first grip and a second grip. The gas cylinder is disposed on the vehicle and configured to supply a gas to an inside of the wafer container. The first grip is slidably disposed on the vehicle. The second grip is slidably disposed on the vehicle. The first grip and the second grip are configured to grip the wafer container.

### BACKGROUND

As process running, a central engine will dispatch an AMHS (Automatic Material Handling System) carrying a target to an assigned process tool for further recipe treatment. The queuing time depends on the distance from current process tool to next targeted one. Wafer transportation relies on AMHS, and longer distance induces more queuing time. Under specific temperature/humidity conditions, longer queuing could induce quality loss. Thus, how to improve the aforementioned problems is one of the goals of those in this technical field.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a functional block diagram of a transport device according to an embodiment of the present disclosure;

FIG. 2A illustrates a schematic diagram of the transport system in FIG. 1 aligned with a wafer container and a semiconductor process equipment;

FIG. 2B illustrates a schematic diagram of a first grip and a second grip gripping the wafer container;

FIG. 2C illustrates a schematic diagram of the transport device in FIG. 2B controlling the base to move upward;

FIGS. 3A to 3F illustrate schematic diagrams of the tracks T1 according to a number of embodiments of the present disclosure;

FIGS. 4A and 4B illustrate block diagrams of elevation views of a driving mechanism of the transport device in different viewing directions;

FIG. 5 illustrates a schematic diagram of a connection view of the second driving motor, the lead screw, the first grip and the second grip;

FIG. 6 illustrates a schematic diagram of a flow chart of an operation method for a transport device in FIG. 1 according to an embodiment; and

FIG. 7 illustrates a schematic diagram of a flow chart of an operation method for the transport device in FIG. 1 according to another embodiment.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

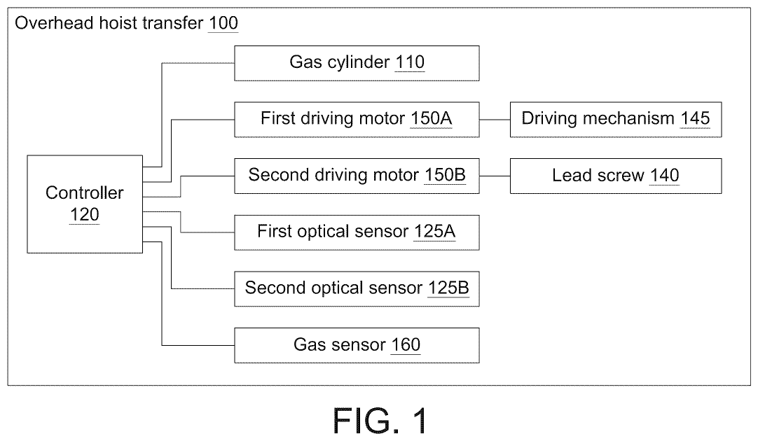

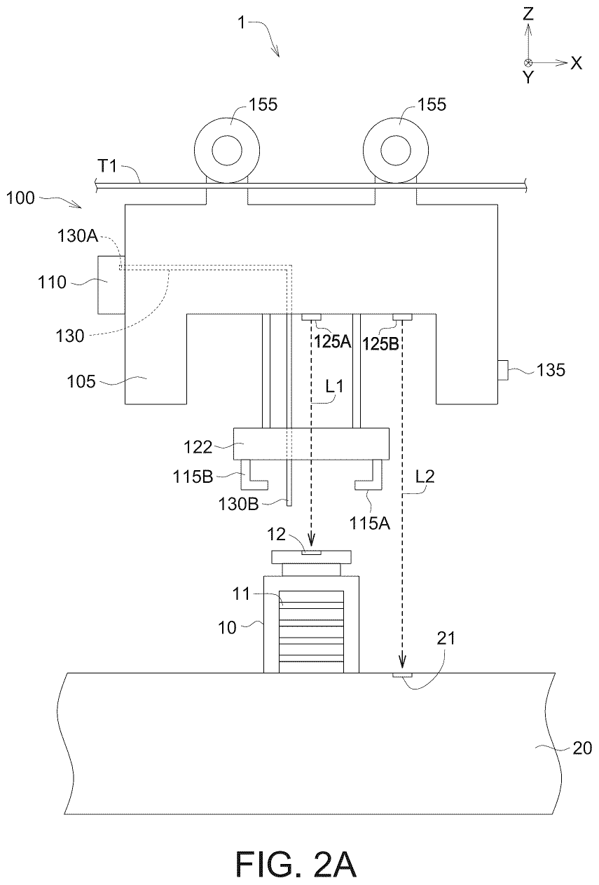

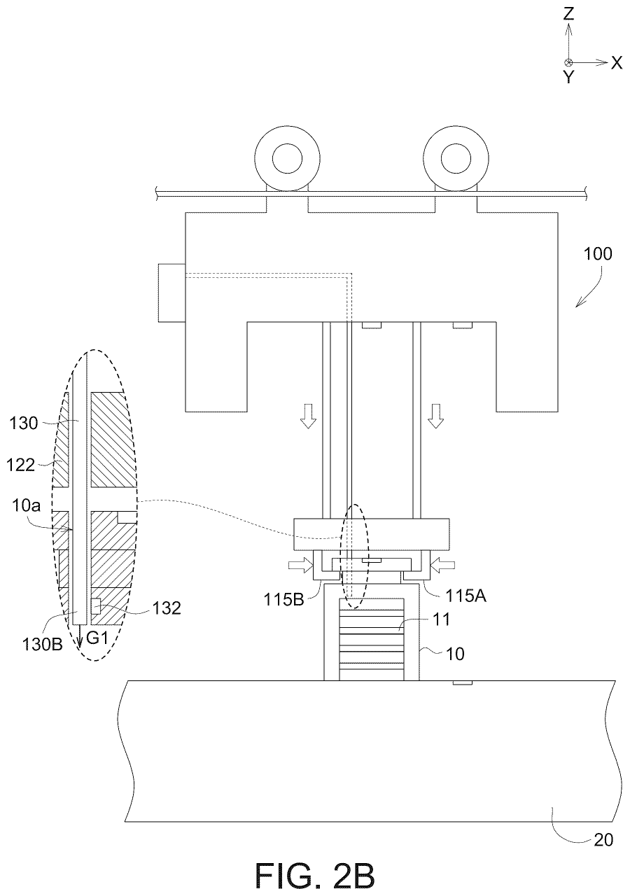

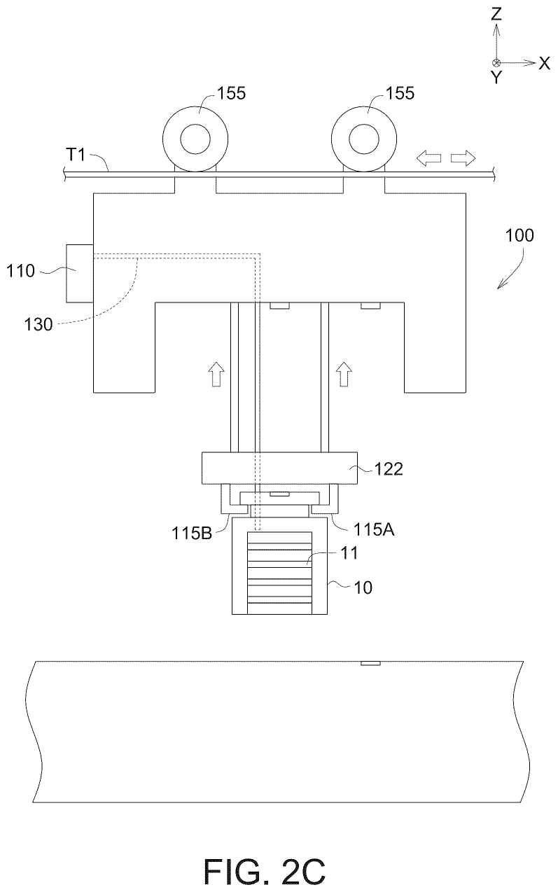

Referring to FIGS. 1 to 2C, FIG. 1 illustrates a functional block diagram of a transport device according to an embodiment of the present disclosure, FIG. 2A illustrates a schematic diagram of the transport system 100 in FIG. 1 aligned with a wafer container 10 and a semiconductor process equipment 20, FIG. 2B illustrates a schematic diagram of a first grip 115A and a second grip 115B gripping the wafer container 10, and FIG. 2C illustrates a schematic diagram of the transport device 100 in FIG. 2B controlling the base 122 to move upward.

As illustrated in FIG. 1, the transport device 100 mentioned here, not limited to OHT (Overhead Hoist Transfer), also including AGV (Automated Guided Vehicle) or other applications. The transport device 100 includes a vehicle 105, a gas cylinder 110, a first grip 115A, a second grip 115B, a controller 120, a base 122, a first optical sensor 125A, a second optical sensor 125B, a gas tube 130, an object sensor 132, a gas sensor 135, a lead screw 140, a driving mechanism 145, a first driving motor 150A, a second driving motor 150B and at least one roller 155.

As illustrated in FIG. 2A, a transport system 1 includes the transport device 100 and at least one track T1. The transport device 100 is movably connected to the track T1. The transport device 100 may be applied to, for example, an AMHS (Automatic Material Handling System). The transport device 100 is configured to hold or grip a wafer container 10. The gas cylinder 110 is disposed on the vehicle 105 and configured to supply a gas G1 to an inside of the wafer container 10 (or referred to as “Front Opening Unified Pod (FOUP)”). The first grip 115A is slidably disposed on the vehicle 105. The second grip 115B is slidably disposed on the vehicle 105. The first grip 115A and the second grip 115B are configured to grip the wafer container 10. In the present embodiment, the transport device 100 itself may carry the gas cylinder 110, and thus the wafer container 10 is not required to be transported to a gas supply equipment by the transport device 100, and a longer queuing for the gas supply equipment is not needed. In addition, the gas G1 is an inert gas, such as nitrogen, helium, etc. The gas G1 may expel toxic gases in the wafer container 10, reduce a temperature and/or a humidity in the wafer container 10 and/or prevent a wafer 11 in the wafer container 10 from being oxidized. At least one wafer 11 may be accommodated in the wafer container 10.

As illustrated in FIGS. 2A and 2B, the gas cylinder 110 is disposed on the vehicle 105. The gas cylinder 110 may supply the gas G1 to the wafer container 10 through the gas tube 130. In other words, the transport device 100 itself may supply the gas G1 for the wafer container 10 in transporting process of the wafer container 10. In addition, the controller 120 may assign the transport device 100 which carries the gas cylinder 110 filled with a suitable gas to grip the wafer container 10. Alternatively, the controller 120 may control the transport devices 100 to replace the gas cylinder 110 (which is filled with inappropriate gas or whose gas is insufficient) with another gas cylinder 110 filled with the suitable gas. Alternatively, the controller 120 may assign the transport device 100 which does not include the gas cylinder to carry the gas cylinder 110. Alternatively, the controller 120 may assign the transport device 100 which includes the gas cylinder to unload the gas cylinder 110. In addition, the controller 120 may recognize the identification of the gas cylinder 110 thorough reading a code (for example, bar code) on the gas cylinder 110.

As illustrated in FIG. 2A, the first grip 115A and the second grip 115B are disposed on the base 122 of the transport device 100. Furthermore, the first grip 115A and the second grip 115B are slidably disposed on the base 122. The first grip 115A and the second grip 115B may move (for example, translate) in X-axis. The first grip 115A and the second grip 115B may move close to each other for gripping the wafer container 10, or move far away from each other for releasing the wafer container 10.

As illustrated in FIG. 2A, the controller 120 is electrically connected to the first optical sensor 125A, the second optical sensor 125B, the object sensor 132, the gas sensor 135, the driving mechanism 145, the first driving motor 150A and the second driving motor 150B by using a wired technology or a wireless communication technology.

As illustrated in FIG. 2A, the first optical sensor 125A and the second optical sensor 125B are disposed on the vehicle 105. The first optical sensor 125A is configured to detect whether the wafer container 10 is aligned with the vehicle 105. Furthermore, the first optical sensor 125A may emit a first detection light L1 downward. When the first detection light L1 is reflected by a reflector 12 of the wafer container 10, the reflected light may be detected by the first optical sensor 125A. The second optical sensor 125B is configured to detect whether the semiconductor process equipment 20 is aligned with the vehicle 105. Furthermore, the second optical sensor 125B may emit a second detection light L2 downward. When the second detection light L2 is reflected by a reflector 21 of the semiconductor process equipment 20, the reflected light may be detected by the second optical sensor 125B. In an embodiment, the semiconductor process equipment 20 may perform, for example, lithographic, dry etching, wet etching, CVD (chemical vapor deposition), PVD (Physical vapor deposition), CMP (Chemical-Mechanical Polishing), furnace, iron implant, etc.

As illustrated in FIGS. 2A and 2B, in an embodiment, when the reflected light of the first detection light L1 is detected by the first optical sensor 125A and simultaneously the reflected light of the second detection light L2 is detected by the second optical sensor 125B (as illustrated in FIG. 2A), the controller 120 controls the vehicle 105 to move to the semiconductor process equipment 20 and then control the first grip 115A and the second grip 115B to grip the wafer container 10 (as illustrated in FIG. 2B).

As illustrated in FIG. 2A, the controller 120 is electrically connected with the first optical sensor 125A and the second optical sensor 125B. In an embodiment, the controller 120 is configured to control the first grip 115A and the second grip 115B to grip the wafer container 10 when the wafer container 10 is aligned with the vehicle 105, for example, the reflected light of the first detection light L1 is detected by the first optical sensor 125A. In another embodiment, the controller 120 is configured to control the vehicle 105 to move to the semiconductor process equipment 20 when the semiconductor process equipment 20 is aligned with the vehicle 105, for example, the reflected light of the second detection light L2 is detected by the second optical sensor 125B.

As illustrated in FIG. 2C, the controller 120 is configured to control the base 122 move upward and control the vehicle 105 to transport the wafer container 10 to the next station.

As illustrated in FIG. 2B, the gas tube 130 includes a first end 130A and a second end 130B. The first end 130A is connected with the gas cylinder 110, and the second end 130B is configured to be connected with the wafer container 10. In an embodiment, the wafer container 10 has a hole 10a, the object sensor 132 is disposed on the hole 10a. For example, the object sensor 132 may be embedded in an sidewall of the hole 10a and exposed from a lateral surface of the hole 10a for detecting the gas tube 130. The base 122 move toward the wafer container 10 until the second end 130B of the gas tube 130 enters the hole 10a and is detected by the object sensor 132. The controller 120 may control the gas cylinder 110 to supply the gas G1 to the inside of the wafer container 10 when the object sensor 132 detects the second end 130B. In an embodiment, the object sensor 132 is, for example, an optical sensor, a proximity sensor, etc. In another embodiment, the controller 120 may control the gas cylinder 110 to supply the gas G1 to the inside of the wafer container 10 when the first grip 115A and the second grip 115B grip the wafer container 10.

As illustrated in FIGS. 2A and 2B, the gas sensor 135 is disposed on the vehicle 105 and configured to detect a gas centration of an environment. The controller 120 is configured to determine whether the gas centration is greater than a preset centration value, and control the gas cylinder to stop supplying the gas G1 to the inside of the wafer container 10 or reduce the supplying volume of the gas G1 when the gas centration is greater than the preset centration value. As a result, it may prevent excessive gas concentration in the environment from harming people in the environment. In addition, the gas sensor 135 further may detect the temperature and/or the humidity of the environment. In an embodiment, the preset centration value may range between 0% and 90%, or even less or even greater.

As illustrated in FIG. 2A, the roller 155 is pivotally connected with the vehicle 105. The roller 155 is slidably connected with a track T1 of the AMHS and the vehicle 105 may be transported to a station along the track T1 through the rotation of the roller 155. Although not illustrated, a motor may connects the roller 155 and drives the roller 155 to rotate.

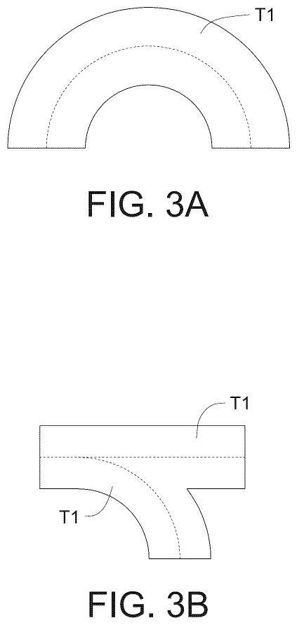

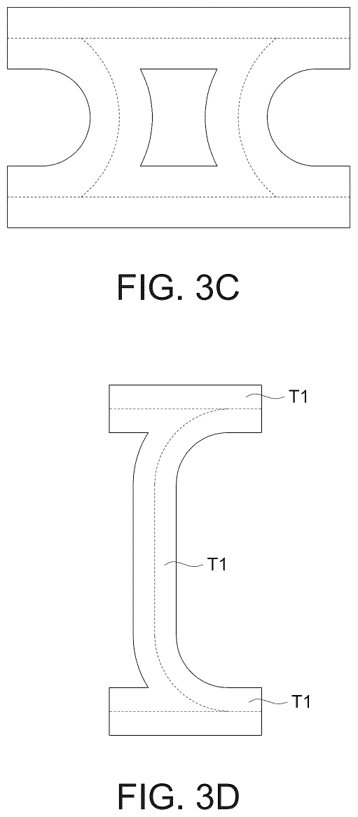

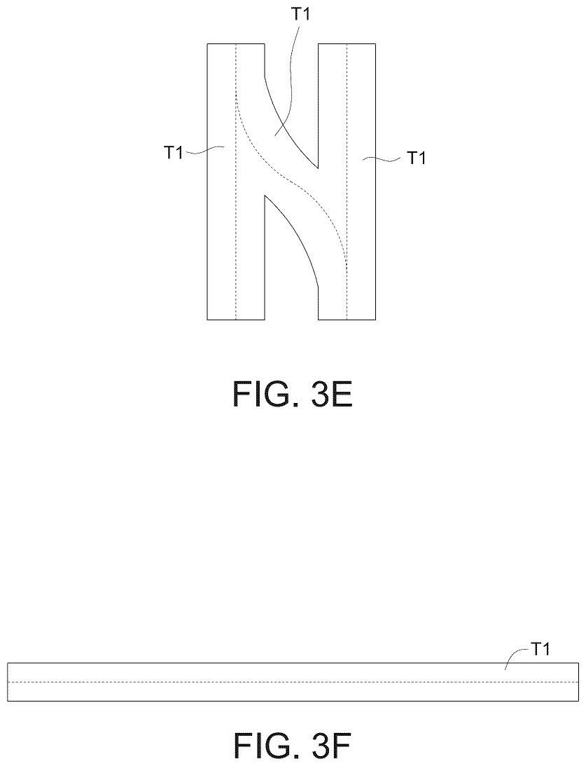

Referring to FIGS. 3A to 3F, FIGS. 3A to 3F illustrate schematic diagrams of the tracks T1 according to a number of embodiments of the present disclosure. The track T1 may extend in a straight line, a curved line or a combination thereof. For example, the track T1 may extend in a semicircular shape, an arc shape, a curved shape, etc.

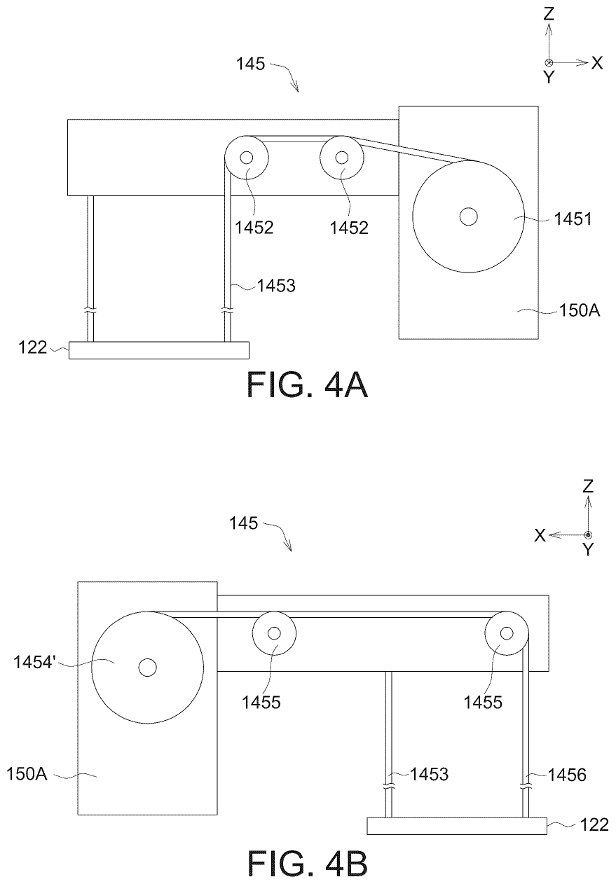

Referring to FIGS. 4A and 4B, FIGS. 4A and 4B illustrate schematic diagrams of elevation views of a driving mechanism 145 of the transport device 100 in different viewing directions.

As illustrated in FIGS. 4A and 4B, the driving mechanism 145 is connected with the base 122 and configured to drive the base 122 up and down. The first driving motor 150A is disposed in the base 122 and connected with the driving mechanism 145. The controller 120 is electrically connected with the first driving motor 150A and configured to control the first driving motor 150A to drive the driving mechanism 145. Furthermore, the driving mechanism 145 includes a first driving pulley 1451, at least one first driven pulley 1452, a first belt 1453, a second driving pulley 1454, at least one second driven pulley 1455 and a second belt 1456. The first driving motor 150A is disposed in the base 122. The first driving motor 150A is connected with the first driving pulley 1451 for driving the first driving pulley 1451 to rotate around +/−Y axis. The first belt 1453 is connected with the first driving pulley 1451, the first driven pulleys 1452 and the base 122, and is guided by the first driving pulley 1451 and the first driven pulleys 1452 for driving the base 122 to move up and down (for example, along Z axis). The first driving motor 150A is connected with the second driving pulley 1454 for driving the second driving pulley 1454 to rotate around +/−Y axis. The second belt 1456 is connected with the second driving pulley 1454, the second driven pulleys 1455 and the base 122, and is guided by the second driving pulley 1454 and the second driven pulleys 1455 for driving the base 122 to move up and down (for example, along Z axis). When the first driving pulley 1451 and the second driving pulley 1454 synchronously rotate, the first belt 1453 and the second belt 1456 move by the same displacement along Z axis.

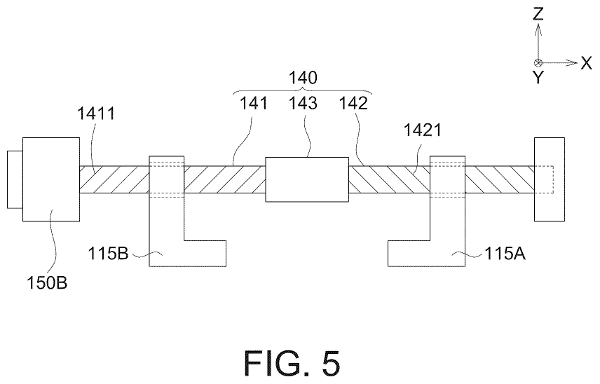

Referring to FIG. 5, FIG. 5 illustrates a schematic diagram of a connection view of the second driving motor 150B, the lead screw 140, the first grip 115A and the second grip 115B.

As illustrated in FIG. 5, the lead screw 140 is connected with the second driving motor 150B and passing through the first grip 115A and the second grip 115B. The controller 120 is electrically connected with the second driving motor 150B and configured to control the second driving motor 150B to drive the lead screw 140 to rotate. In an embodiment, the lead screw 140 includes a first thread segment 141, a second thread segment 142 and a separation segment 143. The separation segment 143 connects the first thread segment 141 with the second thread segment 142. The separation segment 143 has no any thread. The first thread segment 141 has a first male thread 1411, and the second thread segment 143 has a second male thread 1431, wherein the first male thread 1411 and the second male thread 1431 has different thread directions. For example, the first male thread 1411 is a left thread, and the second male thread 1431 is a right thread. The first grip 115A has a female thread screwed with the first male thread 1411, and the second grip 115B has a female thread screwed with the second male thread 1431. Through design of different thread directions, when the lead screw 140 rotates around the same rotation direction, the first grip 115A and the second grip 115B move along different translation directions. For example, when the lead screw 140 rotate around a first rotation direction (for example, +X axis), the first grip 115A and the second grip 115B move close to each other for gripping the wafer container 10 along X axis. When the lead screw 140 rotate around a second rotation direction (for example, −X axis), the first grip 115A and the second grip 115B move far away from each other for releasing the wafer container 10.

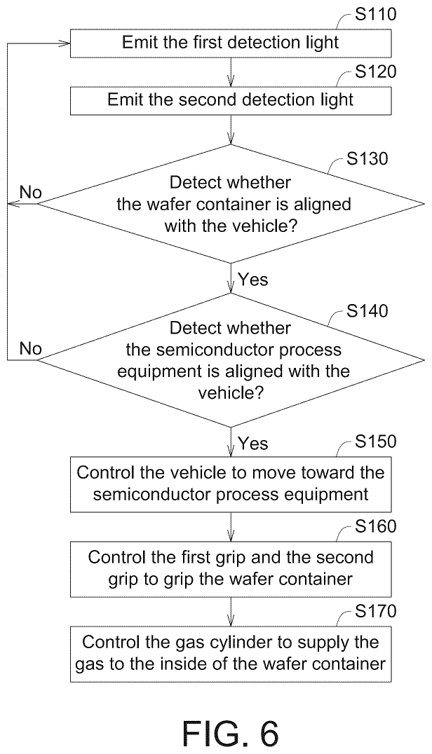

Referring to FIG. 6, FIG. 6 illustrates a schematic diagram of a flow chart of an operation method for a transport device 100 in FIG. 1 according to an embodiment.

In step S110, as illustrated in FIG. 2A, the first optical sensor 125A emits the first detection light L1. Furthermore, the controller 120 controls the first optical sensor 125A to emit the first detection light L1 downward.

In step S120, as illustrated in FIG. 2A, the second optical sensor 125B emits the second detection light L2. Furthermore, the controller 120 controls the second optical sensor 125B to emit the second detection light L2 downward.

In step S130, as illustrated in FIG. 2A, whether the wafer container 10 is aligned with the vehicle 105 of the transport device 100 is detected. Furthermore, when the first detection light L1 is reflected by the reflector 12 of the wafer container 10, the reflected light may be detected by the first optical sensor 125A, and the process proceeds to step S140. When the first optical sensor 125A does not detect any reflected light, the process proceeds back step S110.

In step S140, as illustrated in FIG. 2A, whether the semiconductor process equipment 20 is aligned with the vehicle 105 of the transport device 100 is detected. Furthermore, when the second detection light L2 is reflected by the reflector 21 of the semiconductor process equipment 20, the reflected light may be detected by the second optical sensor 125B, and the process proceeds to step S150. When the second optical sensor 125B does not detect any reflected light, the process proceeds back step S110.

In step S150, as illustrated in FIG. 2A, the controller 120 controls the vehicle 105 to move toward the semiconductor process equipment 20. Furthermore, as illustrated in FIG. 2B, the controller 120 controls the first driving motor 150A to drive the first driving pulley 1451 and the second driving pulley 1454 to rotate to drive the first belt 1453 and the second belt 1456 to move the base 122 toward the wafer container 10.

In step S160, as illustrated in FIG. 2B, the first grip 115A and the second grip 115B are controlled to grip the wafer container 10. Furthermore, as illustrated in FIG. 2B, when the first grip 115A and the second grip 115B are aligned with the wafer container 10, the controller 120 controls the second driving motor 150B to drive the lead screw 140 to rotate around, for example, +X axis, and synchronously the first grip 115A and the second grip 115B move close to each other for gripping the wafer container 10 along X axis.

In step S170, as illustrated in FIG. 2B, the gas cylinder 110 is controlled to supply the gas G1 to the inside of the wafer container 10. Furthermore, when the object sensor 132 detects the second end 130B enters the hole 10a, the controller 120 controls the gas cylinder 110 to supply the gas G1 to the inside of the wafer container 10.

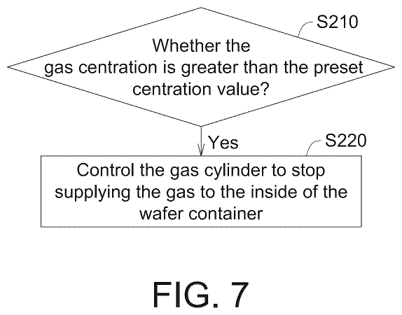

Referring to FIG. 7, FIG. 7 illustrates a schematic diagram of a flow chart of an operation method for the transport device 100 in FIG. 1 according to another embodiment.

In step S210, whether the gas centration is greater than the preset centration value. Furthermore, the gas sensor 135 detects the gas centration. The controller 120 determines whether the gas centration is greater than the preset centration value. When the gas centration is greater than the preset centration value, the process proceeds to step S220. When the gas centration is not greater than the preset centration value, the process proceeds back step S170.

In step S220, the controller 120 controls the gas cylinder 110 to stop supplying the gas G1 to the inside of the wafer container 10 when the gas centration is greater than the preset centration value. In an embodiment, the gas cylinder 110 includes a valve (not illustrated) which is electrically connected with the controller 120. The valve may selectively open or close. When the valve opens, the gas G1 may be transmitted through the valve. When the valve closes, the gas G1 cannot pass through the valve.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a transport device includes a vehicle and a gas cylinder. The gas cylinder may be disposed on the vehicle and configured to supply a gas to an inside of the wafer container. The transport device itself may provide a real-time gas treatment for the wafer container in transporting process of the wafer container.

Example embodiment 1: a transport device, for holding a wafer container, includes a vehicle, a gas cylinder, a first grip and a second grip. The gas cylinder is disposed on the vehicle and configured to supply a gas to an inside of the wafer container. The first grip is slidably disposed on the vehicle. The second grip is slidably disposed on the vehicle. The first grip and the second grip are configured to grip the wafer container.

Example embodiment 2 based on Example embodiment 1: the transport device further includes a base and a driving mechanism. The first grip and the second grip are disposed on the base. The driving mechanism is connected with the base configured to drive the base up and down.

Example embodiment 3 based on Example embodiment 2: the transport device further includes a first driving motor disposed in the base and connected with the driving mechanism.

Example embodiment 4 based on Example embodiment 3: the transport device further includes a controller electrically connected with the first driving motor and configured to control the first driving motor to drive the driving mechanism.

Example embodiment 5 based on Example embodiment 1: the transport device further includes a gas tube including a first end and a second end. The first end is connected with the gas cylinder, and the second end is configured to connect with the wafer container.

Example embodiment 6 based on Example embodiment 1: the transport device further includes a second driving motor and a lead screw connected with the second driving motor and screwed with the first grip and the second grip.

Example embodiment 7 based on Example embodiment 6: the transport device further includes a controller electrically connected with the second driving motor and configured to control the second driving motor to drive the lead screw to rotate.

Example embodiment 8 based on Example embodiment 1: the transport device further includes a gas sensor disposed on the vehicle and configured to detect a gas centration.

Example embodiment 9 based on Example embodiment 8: the transport device further includes a controller electrically connected with the gas sensor and configured to determine whether the gas centration is greater than a preset centration value; and when the gas centration is greater than the preset centration value, control the gas cylinder to stop supplying the gas to the inside of the wafer container.

Example embodiment 10 based on Example embodiment 1: the gas is an inert gas.

Example embodiment 11 based on Example embodiment 1: the transport device further includes a first optical sensor and a controller. The first optical sensor is disposed on the vehicle and configured to detect whether the wafer container is aligned with the vehicle. The controller is electrically connected with the first optical sensor and configured to control the first grip and the second grip to grip the wafer container when the wafer container is aligned with the vehicle.

Example embodiment 12 based on Example embodiment 11: the controller is further configured to control the gas cylinder to supply the gas to the inside of the wafer container when the wafer container is gripped by the first grip and the second grip.

Example embodiment 13 based on Example embodiment 1: the transport device further includes a second optical sensor and a controller. The second optical sensor is disposed on the vehicle and configured to detect whether a semiconductor process equipment is aligned with the vehicle. The controller is electrically connected with the second optical sensor and configured to control the vehicle to move to the semiconductor process equipment.

Example embodiment 14: a transport system, for transporting a wafer container, includes a track and a transport device movably connected to the track. The transport device, for holding the wafer container, includes a vehicle, a gas cylinder, a first grip and a second grip. The gas cylinder is disposed on the vehicle and configured to supply a gas to an inside of the wafer container. The first grip is slidably disposed on the vehicle. The second grip is slidably disposed on the vehicle. The first grip and the second grip are configured to grip the wafer container.

Example embodiment 15 based on Example embodiment 14: the transport system further includes a first optical sensor, a second optical sensor and a controller. The first optical sensor is disposed on the vehicle and configured to detect whether the wafer container is aligned with the vehicle. The second optical sensor is disposed on the vehicle and configured to detect whether a semiconductor process equipment is aligned with the vehicle. The controller is electrically connected with the first optical sensor and the second optical sensor and configured to control the first grip and the second grip to grip the wafer container when the wafer container is aligned with the vehicle and the semiconductor process equipment is aligned with the vehicle by a second optical sensor.

Example embodiment 16: an operation method of an transport device includes the following steps: providing an transport device, wherein the transport device includes a vehicle, a gas cylinder, a first grip and a second grip, the gas cylinder is disposed on the vehicle, the first grip and the second grip are slidably disposed on the vehicle; gripping the wafer container by the first grip and the second grip; and supplying a gas to an inside of the wafer container when the wafer container is gripped by the first grip and the second grip.

Example embodiment 17 based on Example embodiment16: the transport device further includes a base and a driving mechanism connected with the base. The operation method further includes: driving the base up and down by the driving mechanism.

Example embodiment 18 based on Example embodiment 16: the transport device further includes a second driving motor and a lead screw connected with the second driving motor and screwed with the first grip and the second grip. The operation method further includes: controlling the second driving motor to drive the lead screw to rotate.

Example embodiment 19 based on Example embodiment 16: the operation method further includes: detecting a gas centration by a gas sensor; determining whether the gas centration is greater than a preset centration value; and when the gas centration is greater than the preset centration value, controlling the gas cylinder to stop supplying the gas to the inside of the wafer container.

Example embodiment 20 based on Example embodiment 16: the operation method further includes: detect whether the wafer container is aligned with the vehicle by a first optical sensor; detect whether a semiconductor process equipment is aligned with the vehicle by a second optical sensor; and control the first grip and the second grip to grip the wafer container when the wafer container is aligned with the vehicle and the semiconductor process equipment is aligned with the vehicle by a second optical sensor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An transport device, for holding a wafer container, comprising:
a vehicle;
a gas cylinder disposed on the vehicle and configured to supply a gas to an inside of the wafer container;
a first grip slidably disposed on the vehicle; and
a second grip slidably disposed on the vehicle;
wherein the first grip and the second grip are configured to grip the wafer container.

2. The transport device according to claim 1, further comprising:
a base, wherein the first grip and the second grip are disposed on the base;
a driving mechanism connected with the base configured to drive the base up and down.

3. The transport device according to claim 2, further comprising:
a first driving motor disposed in the base and connected with the driving mechanism.

4. The transport device according to claim 3, further comprising:
a controller electrically connected with the first driving motor and configured to control the first driving motor to drive the driving mechanism.

5. The transport device according to claim 1, further comprising:
a gas tube comprising a first end and a second end;
wherein the first end is connected with the gas cylinder, and the second end is configured to connect with the wafer container.

6. The transport device according to claim 1, further comprising:
a second driving motor; and
a lead screw connected with the second driving motor and screwed with the first grip and the second grip.

7. The transport device according to claim 6, further comprising:
a controller electrically connected with the second driving motor and configured to control the second driving motor to drive the lead screw to rotate.

8. The transport device according to claim 1, further comprising:
a gas sensor disposed on the vehicle and configured to detect a gas centration.

9. The transport device according to claim 8, further comprising:
a controller electrically connected with the gas sensor and configured to:
determine whether the gas centration is greater than a preset centration value; and
when the gas centration is greater than the preset centration value, control the gas cylinder to stop supplying the gas to the inside of the wafer container.

10. The transport device according to claim 1, wherein the gas is an inert gas.

11. The transport device according to claim 1, further comprising:
a first optical sensor disposed on the vehicle and configured to detect whether the wafer container is aligned with the vehicle; and
a controller electrically connected with the first optical sensor and configured to control the first grip and the second grip to grip the wafer container when the wafer container is aligned with the vehicle.

12. The transport device according to claim 11, wherein the controller is further
configured to:
control the gas cylinder to supply the gas to the inside of the wafer container when the wafer container is gripped by the first grip and the second grip.

13. The transport device according to claim 1, further comprising:
a second optical sensor disposed on the vehicle and configured to detect whether a semiconductor process equipment is aligned with the vehicle; and
a controller electrically connected with the second optical sensor and configured to control the vehicle to move to the semiconductor process equipment.

14. A transport system, for transporting a wafer container, comprising:
a track; and
a transport device movably connected to the track, and comprising:
a vehicle;
a gas cylinder disposed on the vehicle and configured to supply a gas to an inside of the wafer container;
a first grip slidably disposed on the vehicle; and
a second grip slidably disposed on the vehicle;
wherein the first grip and the second grip are configured to grip the wafer container.

15. The transport system according to claim 14, further comprising:
a first optical sensor disposed on the vehicle and configured to detect whether the wafer container is aligned with the vehicle;
a second optical sensor disposed on the vehicle and configured to detect whether a semiconductor process equipment is aligned with the vehicle; and
a controller electrically connected with the first optical sensor and the second optical sensor and configured to control the first grip and the second grip to grip the wafer container when the wafer container is aligned with the vehicle and the semiconductor process equipment is aligned with the vehicle by a second optical sensor.

16. An operation method, comprising:
providing an transport device, wherein the transport device comprises a vehicle, a gas cylinder, a first grip and a second grip, the gas cylinder is disposed on the vehicle, the first grip and the second grip are slidably disposed on the vehicle;
gripping the wafer container by the first grip and the second grip; and
supplying a gas to an inside of the wafer container when the wafer container is gripped by the first grip and the second grip.

17. The operation method according to claim 16, whether the transport device further comprises a base and a driving mechanism connected with the base; the operation method further comprises:
driving the base up and down by the driving mechanism.

18. The operation method according to claim 16, whether the transport device further comprises a second driving motor and a lead screw connected with the second driving motor and screwed with the first grip and the second grip; the operation method further comprises:
controlling control the second driving motor to drive the lead screw to rotate.

19. The operation method according to claim 16, further comprising:
detecting a gas centration by a gas sensor;
determining whether the gas centration is greater than a preset centration value; and
when the gas centration is greater than the preset centration value, controlling the gas cylinder to stop supplying the gas to the inside of the wafer container.

20. The operation method according to claim 16, further comprising:
detecting whether the wafer container is aligned with the vehicle by a first optical sensor;
detecting whether a semiconductor process equipment is aligned with the vehicle by a second optical sensor; and
controlling the first grip and the second grip to grip the wafer container when the wafer container is aligned with the vehicle and the semiconductor process equipment is aligned with the vehicle by a second optical sensor.
